(19) United States
(12) Patent Application Publication
(10) Pub. No.: US 2003/0164450 A1
(43) Pub. Date: Sep. 4, 2003

(54) Thermal radiation detection device, method for producing the same and use of said device

(76) Inventors: Rainer Bruchhaus, Kanagawa-ken (JP); Dana Pitzer, Unterschleissheim (DE); Axel Schubert, Munchen (DE); Bernhard Winkler, Munchen (DE)

Correspondence Address: YOUNG & THOMPSON, 745 SOUTH 23RD STREET 2ND FLOOR, ARLINGTON, VA, 22202

(21) Appl. No.: 10/240,241

(22) PCT Filed: Mar. 21, 2001
(86) PCT No.: PCT/DE01/01083

(30) Foreign Application Priority Data
Mar. 29, 2000 (DE) 10015687.8

(51) Int. Cl. G01J 5/20; H01L 27/14; H01L 31/00

(52) U.S. Cl. 250/338.4

(57) ABSTRACT

The invention relates to a device for detecting thermal radiation (3), comprising at least one thermal detector element (2) that converts the thermal radiation into an electric signal (4). The inventive device is further provided with at least one focusing element (12) that focuses the thermal radiation onto the detector element. The focusing element is for example a lens that consists of a semiconducting material such a silicon. Preferably, the focusing element is integrated in the detection window for detecting the thermal radiation, said detection window consisting of a semiconducting material.

The invention relates to a device for detection of thermal radiation with at least one thermal detector element for converting the thermal radiation into an electrical signal. In addition to the device, a process for producing the device and use of the device are given.

A device of the indicated type is known for example from DE 196 45 036 A1. Here a thermal detector element is connected to a carrier body (substrate) of silicon. The detector element is a pyroelectric detector element. It has a layer structure with two electrodes and a pyroelectric layer located between the electrodes, with pyroelectrically sensitive material. This material is lead zirconate titanate (PZT). The electrodes consist for example of platinum or of a chromium nickel alloy which absorbs the thermal radiation.

The object of the invention is to show how the existing thermal radiation can be better used compared to the indicated prior art in a device for detection of thermal radiation.

To achieve the object a device for detection of thermal radiation with at least one thermal detector element for converting the thermal radiation into an electrical signal is given. The device is characterized in that there is at least one focusing element with a semiconducting material for focusing of thermal radiation on the detector element.

The thermal radiation to be detected is collected by focusing and directed at the detector element. In this way it is possible for more thermal radiation to reach the detector element for the same base area of the detector element compared to the prior art. A larger electrical signal and thus greater sensitivity to thermal radiation result.

The thermal radiation (infrared radiation) which can be detected with the device has especially a wavelength of more than 1 micron. Preferably the wavelength of the thermal radiation is selected from the range from 5 microns to 15 microns.

The thermal detector element is used to convert thermal energy in the form of thermal radiation into electrical energy. The thermal detector element is based for example on the Seebeck effect or the pyroelectric effect. The prerequisite for this is absorption of thermal radiation by the thermally sensitive material of the detector element which triggers the corresponding effect. Absorption takes place directly by the thermally sensitive material. But it is also conceivable for the thermal radiation to be absorbed by the electrode of the detector element. Moreover it is also possible for the thermal radiation to be absorbed by an absorption article in the immediate vicinity of the detector element and for the amount of heat absorbed thereby to be dissipated by convection or thermal conduction to the thermally sensitive material. The absorption article acts as an energy transmitter.

The focusing element is designed to provide for the thermal radiation for absorption to be directed at the detector element and/or the absorption article. A focusing element in the form of a mirror is also conceivable. The mirror has a surface with high reflection for the thermal radiation.

In one special embodiment the focusing element is a lens. The lens has a certain transmission for the thermal radiation in the direction of the detector element or of the absorption article. The transmission is as high as possible. It is more than 50%, but especially more than 70% to almost 100%.

In one special embodiment there is a detection window which has a focusing element for irradiation of the detector element with thermal radiation. The detection window provides for the thermal radiation to be able to strike the detector element and/or the absorption article. The focusing element moreover provides for focusing of the thermal radiation. Advantageously the detection window has the same transmission property as the focusing element. The focusing element can be integrated in the detection window. But it can also be the detection window itself.

In one special embodiment the detection window and/or the focusing element has a semiconducting material which is chosen from the group germanium and/or silicon. These materials have sufficient transmission for thermal radiation of a wavelength of 5 microns to 15 microns. The focusing element or the detection window is formed directly from the semiconducting material.

In another embodiment there are a carrier body which has a detection window with the focusing element and/or a housing of the detector element which has the detection window with the focusing element. The detection window is integrated especially in the carrier body. The carrier body acts itself as a detection window. The detector element is irradiated through the carrier body. Alternatively the irradiation of the detector element can take place from the side facing away from the carrier body. For this purpose the carrier body is located for example in a housing. The housing has a wall with the detection window. The housing is for example a jacket for protection of the detector element against environmental effects. The environmental effect is for example dirt, atmospheric humidity or a chemical etchant which would attack the detector element. The environmental effect could endanger the serviceability of the detector element.

In one special embodiment the thermal detector element is a pyroelectric detector element. The pyroelectric detector element consists of a pyroelectric layer with a pyroelectrically sensitive material. This material is for example a ceramic, such as lithium niobate (LiNbO₃) or lead zirconate titanate. A ferroelectric polymer such as polyvinylidene fluoride (PVDF) is also conceivable. The pyroelectric layer with the pyroelectrically sensitive material on two opposing sides has at least one electrode layer each. For example platinum or a platinum alloy is possible as the electrode material of the electrode layer. A chromium nickel alloy or an electrically conductive oxide such as strontium ruthenate (SrRuO₃) is also conceivable. The detector element has for example a rectangular base surface with an edge length of 25 microns to 200 microns.

In one special embodiment there is at least one focusing array with several focusing elements. It is advantageous if there is a detector array with several detector elements at the same time. A focusing element or a detector element is a pixel of the focusing array or of the detector array. The arrays are characterized for example by a column-shaped and line-shaped arrangement of their elements. In a line-shaped arrangement of the elements the elements are distributed one-dimensionally in one direction. In a column-shaped and line-shaped arrangement there is a two-dimensional distribution. The focusing array and/or the detector array consist for example of 20×20 individual elements. An arbitrary, flat distribution of elements is also conceivable.

Using the detector array it is possible to achieve local resolution of the thermal radiation. In particular one focusing element is assigned to exactly one detector element of the detector array. The thermal radiation is focussed by the focusing element only on one detector element. In this way increased local resolution can be achieved. Here several focusing elements can be assigned to one detector element.

An additional increase of local resolution can be achieved in that the focusing elements are insulated against one another with respect to the thermal radiation. For example, there is one layer at a time which is opaque, therefore not transparent, to thermal radiation, between the individual focusing elements. One such layer is for example a highly reflecting metal layer. But it is also conceivable for the focusing elements to be separate from one another. In the passage of the thermal radiation from one focusing element to the adjacent focusing element there are at least two phase transitions. There is a loss of intensity of the thermal radiation passing from one focusing element to the other and thus there is increased local resolution of detection of thermal radiation.

In addition to the device, to achieve the object, a process for producing a device for detection of thermal radiation which was described above is given. According to the process at least one focusing element with semiconducting material is produced in a detection window which has semiconducting material for irradiation of the detector element with thermal radiation.

In one special embodiment a semiconducting material is used which is chosen from the group of germanium and/or silicon. In particular, in the case of silicon, diverse structuring possibilities or possibilities for integration of an electrical circuit are known from micromechanics. For example, a read-out means for reading out, processing or relaying the electrical signal produced by the detector element can be integrated in the carrier body. The read-out means is produced for example by a process which is known from CMOS technology (complementary metal oxide semiconductors).

The process for producing the focusing element comprises especially the following process steps:

a) Application of an enamel layer with photoenamel on the surface of the detection window with the semiconducting material;

b) Photolithographic structuring of the enamel layer, an enamel cylinder with the photoenamel being formed on the surface of the detection window;

c) Forming the enamel cylinder with the photoenamel into a spherical dome with the photoenamel, and

d) Etching of the photoenamel and of the semiconducting material, the focusing element being formed by etching the shape of the spherical dome into the detection window.

The enamel layer is applied for example by spraying on or electrophoretic deposition of the photoenamel on the surface of the detection window. Especially an enamel layer is used with a layer thickness which is chosen from the range of 2 microns inclusive to 100 microns inclusive. The photolithographic structuring takes place for example by exposure using a template or by exposure with a convergent light beam (for example, laser beam). The enamel cylinder has for example a square base surface. In particular the base surface of the enamel cylinder is round.

The enamel cylinder with the photoenamel is shaped for example by flow over the enamel cylinder. In doing so the photoenamel is heated and converted into a flowable state. A spherical dome with photoenamel is formed. The spherical dome is a partial sphere, therefore an incomplete sphere. The diameter of the spherical dome is for example chosen from the range of 0.1 inclusive to 2 mm inclusive. The diameter of the spherical dome is advantageously matched to the assigned detector element. Here provisions are made for the possibility of the amount of thermal radiation which is focussed on the detector element to be absorbed by the detector element. This amount of thermal radiation depends for example on the base area of the detector element.

Both photoenamel and also semiconducting material are removed during etching. The shape of the spherical dome is imaged into the detection window. Thus a focusing element results with a diameter of likewise 0.2 to 2 mm. The height of the focusing element in the form of a lens produced in this way is for example 20 microns. The actual size of the lenses depends for example on the focal position which is required for focusing. Etching takes place especially isotropically. But it can also take place anisotropically.

According to another aspect of the invention, the use of the above described device for detection of thermal radiation is indicated, the thermal radiation being incident on the focusing element, being transmitted by the focusing element and being focussed on the detector element and converted into an electrical signal in the detector element. According to the use, irradiation of the detector element can take place by the carrier body or from the side pointing away from the carrier body. The carrier body thus acts either only as a carrier body or also as a carrier body with detection windows and focusing element. If the device has a detector array, the thermal radiation can be detected with local resolution. Local resolution is advantageous for example for a proximity sensor using which the presence of an individual for example in a space will be ascertained.

In summary, the following advantages are associated with the invention compared to the prior art:

Using the focusing element with the semiconducting material it is possible to increase the amount of thermal radiation which reaches the detector element.

The focusing element can be easily and economically integrated in the detection window of the device for detection of thermal radiation.

Integration of the focusing element in the carrier body is especially advantageous. In this way a compact structure of the device is possible.

Increased local resolution is achieved using the focusing array and the detector array.

A device for detection of thermal radiation is described below using several embodiments and the pertinent figures. The figures are schematic and are not to scale.

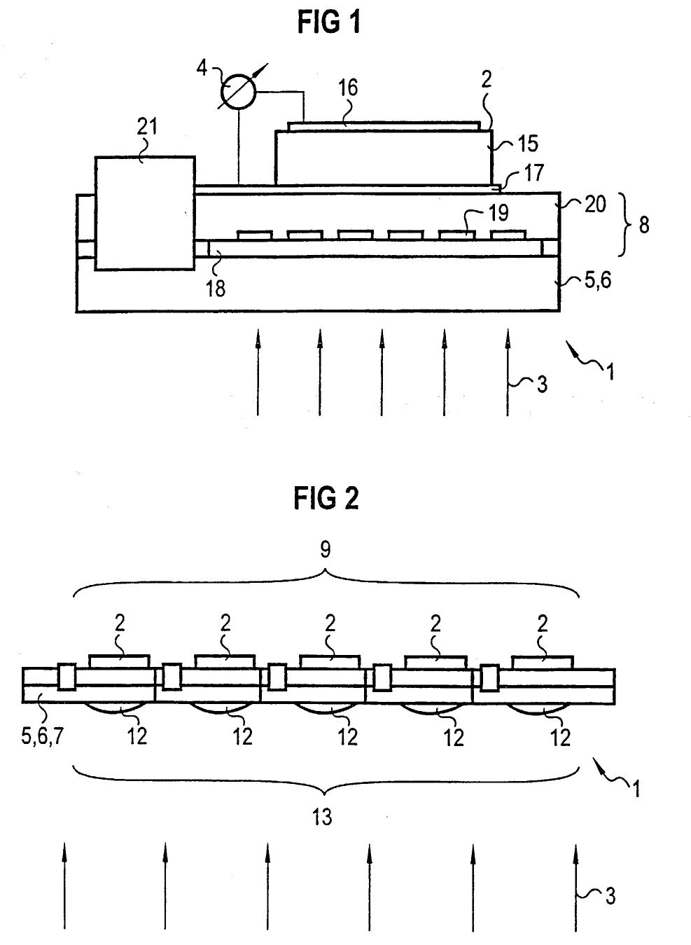

FIG. 1 shows a cross section of a device for detection of thermal radiation with a detector element.

FIG. 2 shows a cross section of a device for detection of thermal radiation with a focusing array and a detector array.

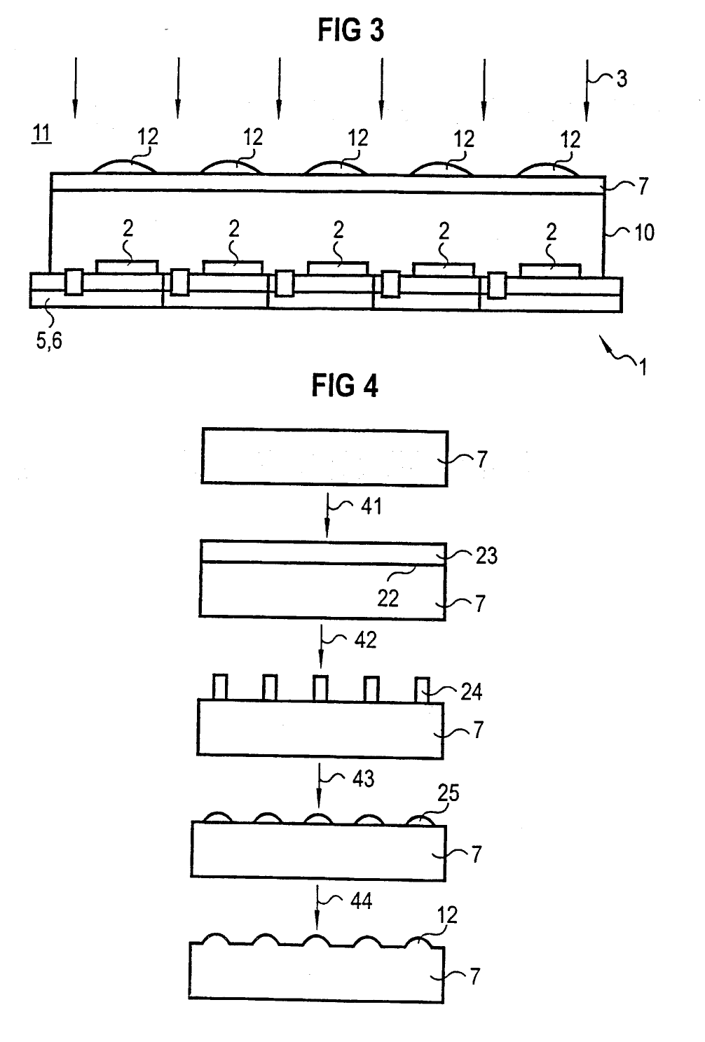

FIG. 3 shows a cross section of a device for detection of thermal radiation with a focusing array and a detector array.

FIG. 4 shows a process for producing the device for detection of thermal radiation.

The device 1 for detection of thermal radiation 3 has a detector array 9 of five pyroelectric detector elements 2 located in a line. One detector element 2 consists of a pyroelectric layer 15 of lead zirconate titanate (FIG. 1). One electrode 16 and 17 at a time is attached to the opposing sides of this layer 15. The electrodes 16 and 17 consist of platinum. The detector element has a rectangular base surface with an edge length of 50 microns. The detector element 2 is located on a carrier body 5 of semiconducting material silicon 6. Between the carrier body 5 and the detector element 2 there is an electrical and thermal insulation layer 8. The insulation layer 8 has a layer-like structure. There is a cavity 18 bordering the carrier body 5 in the insulation layer 8 for thermal insulation of the carrier body 5 and the detector element 2. The cavity 18 is evacuated and extends beyond the base surface of the detector element 2. Moreover the insulation layer 8 has a support layer 19 of polysilicon for support of the cavity 18. Alternatively there is a support layer 19 of silicon nitride. A layer 20 of silicon oxide forms the termination of the insulation layer 8 or the cover of the cavity 18 and of the support layer 19. Moreover there is a read-out means 21. The read-out means 21 amplifies the electrical signal 4 of the detector element 2. The amplified signal is relayed by the read-out means 21.

According to a first embodiment, on one surface of the carrier body 5 which faces away from the detector array 9 there is a focusing array 13 with five focusing elements 12 (FIG. 2). Each of the focusing elements 12 is a lens consisting of silicon 6. The focusing elements 12 are part of the carrier body 5. The detector elements 2 are irradiated by thermal radiation 3 from the side of the carrier body 5. In this embodiment the carrier body 5 is itself the detection window 7 with the focusing element 12. One focusing element 12 is assigned to each detector element 2. One certain segment of thermal radiation 3 at a time is focussed on one detector element 2 at a time using the focusing element 12. In doing so the thermal radiation 3 is incident on the focusing element 12, is transmitted there and is focussed on the assigned detector element 2 and is converted in the detector element 2 into an electrical signal 4.

According to another embodiment, to protect the detector array 9 there is a housing 10 which jackets the detector array 9 (FIG. 3). The housing has a wall which acts as a detection window 7. The detection window 7 is located opposite the detector array 9. The focusing array 13 is integrated in the detection window 7. The focusing array 13 and the detection window 7 consist of silicon 6.

To produce the focusing elements 12 a 20 micron thick enamel layer 23 of photoenamel is applied by spraying on the surface 22 of a 1 mm thick silicon plate which is used as the detection window 7 (FIG. 4, process step 41). This enamel layer 23 is structured photolithographically (process step 42). In doing so enamel cylinders 24 with a round base surface are produced. Furthermore, the enamel cylinders 24 are shaped into spherical domes 25 (process step 43). Afterwards isotropic etching of the photoenamel of the spherical domes and of the silicon takes place (process step 44). The shape of the spherical domes is imaged into the detection window 7 of silicon. A lens 12 is formed from each of the spherical domes. Each spherical dome is characterized by a diameter of roughly 200 microns and a height of 20 microns.

1. Device for detection of thermal radiation (3) with at least one thermal detector element (2) for converting the thermal radiation (3) into an electrical signal (4), characterized in that
there is at least one focusing element (12) with a semiconducting material (6) for focusing of thermal radiation (3) onto the detector element (2).

2. Device as claimed in claim 1, wherein the focusing element (12) is a lens.

3. Device as claimed in claim 1 or 2, wherein there is a detection window (7) which has a focusing element (12) for irradiation of the detector element (2) with thermal radiation (3).

4. Device as claimed in claim 3, wherein the detection window (7) and/or the focusing element (12) has a semiconducting material (6) which is chosen from the group germanium and/or silicon.

5. Device as claimed in claim 3 or 4, wherein there are a carrier body (5) which has a detection window (7) with the focusing element (12) and/or a housing (10) of the detector element (2) which has the detection window (7) with the focusing element (12).

6. Device as claimed in one of claims 1 to 5, wherein there is at least one focusing array (13) with several focusing elements (12).

7. Device as claimed in claim 6, wherein there is at least one detector array (9) with several detector elements (2) and each of the focusing elements (12) of the focusing array (13) is assigned to one detector element (2) of the detector array (9).

8. Process for producing a device for detection of thermal radiation as claimed in one of claims 1 to 8, wherein at least one focusing element (23) with semiconducting material (6) is produced in a detection window (7) which has semiconducting material for irradiation of the detector element (2) with thermal radiation (3).

9. Process as claimed in claim 8, wherein a semiconducting material (6) is used which is chosen from the group germanium and/or silicon.

10. Process as claimed in claim 8 or 9, wherein producing the focusing element (12) encompasses the following process steps:
a) Application of an enamel layer (23) with photoenamel on the surface (22) of the detection window (7) with the semiconducting material;
b) Photolithographic structuring of the enamel layer (23), an enamel cylinder (24) with the photoenamel being formed on the surface (22) of the detection window (7);
c) Forming the enamel cylinder (24) with the photoenamel into a spherical dome (25) with the photoenamel, and
d) Etching of the photoenamel and of the semiconducting material, the focusing element (12) being formed by etching the shape of the spherical dome (25) into the detection window (7).

11. Process as claimed in claim 10, wherein etching takes place isotropically.

12. Use of the device as claimed in one of claims 1 to 7 for detection of thermal radiation, the thermal radiation
i) being incident on the focusing element,
ii) being transmitted by the focusing element and being focussed on the detector element, and
iii) being converted into an electrical signal in the detector element.
